(19) United States
(12) Patent Application Publication
(10) Pub. No.: US 2020/0240009 A1
(43) Pub. Date: Jul. 30, 2020

(54) APPARATUS FOR COATING A BAND-SHAPED SUBSTRATE

(71) Applicant: Fraunhofer-Gesellschaft zur Förderung der angewandten Forschung e.V., Munich (DE)

(72) Inventors: Sebastian Rethberg, Dresden (DE); Steffen Straach, Dresden (DE); Thomas Kühnel, Dresden (DE)

(73) Assignee: Fraunhofer-Gesellschaft zur Förderung der angewandten Forschung e.V., Munich (DE)

(21) Appl. No.: 16/752,227

(22) Filed: Jan. 24, 2020

(30) Foreign Application Priority Data
Jan. 28, 2019 (DE) 10 2019 102 008.5

(51) Int. Cl. C23C 14/56; C23C 14/04

(52) U.S. Cl. CPC C23C 14/562; C23C 14/042

(57) ABSTRACT

A device for coating a band-shaped substrate within a vacuum chamber is provided. The device comprises a coating device; a cooling device with at least one convex surface area which at least partially touches the band-shaped substrate at the time of the coating; and a coil system comprising at least a supply roller, a receiving roller, and multiple guide rollers, wherein the band-shaped substrate includes an electrically conductive material at least on the side where the band-shaped substrate touches the cooling device, wherein the cooling device has an electrically conductive base body and an outer edge layer comprising an electrically insulating material; the coil system is designed to be potential-free with respect to the electrical mass of the device, and an electrical voltage of at least 10 V is formed between the electrically conductive base body, the cooling device, and the electrically conductive material of the substrate.

### CROSS-REFERENCE TO RELATED APPLICATIONS

This application claims priority under 35 USC § 119 to German Patent Application DE 10 2019 102 008.5, filed Jan. 28, 2019, which is hereby incorporated by reference.

### BRIEF DESCRIPTION OF THE DRAWINGS

FIG. 1 shows a schematic sectional view of a device according to the invention; and

FIG. 2 shows a schematic sectional view of an alternative device according to the invention.

### DETAILED DESCRIPTION

The invention relates to a device for coating band-shaped substrates within a vacuum chamber, wherein the band-shaped substrate is cooled during the coating process.

When coating band-shaped substrates in a vacuum, there can easily be irreversible deformation of the substrate due to the energy input affecting the band-shaped substrate during the coating. Such a deformation after overheating of the band-shaped substrate can be caused, for example, by a chemical change of the substrate material, a wrinkle formation, or a plastic over-extension of the substrate. An effective cooling of the band-shaped substrate can help to solve or prevent the problems described above.

Typically, a band-shaped substrate to be coated is continuously rolled off of a supply roller and subsequently continuously rewound on a different roller, the so-called receiving roller. During this winding process, the band-shaped substrate to be coated passes through one or more areas in which a coating takes place. This coating can be realized, for example, by cathode atomization or a vaporization process.

An important group of band-shaped substrates that are coated in a vacuum are plastic films. Typically, during a coating process, plastic films are guided by means of at least one cooling cylinder consisting of a metal material. In the process, they are cooled by way of two essential mechanisms: firstly, through a direct contact between the plastic film and the cooling cylinder, where the contact can be varied to a limited extent by means of band tension on the substrate and the resulting contact pressure on the cooling cylinder; and, secondly, by means of a heat transfer via water molecules, which evaporate from the plastic film and are then trapped between the plastic film and the cooling cylinder.

It is known that, in the vast number of coating processes of plastic films, the second of the two cooling mechanisms is dominant, and only this cooling mechanism ensures sufficient cooling for the feasibility of the process. The coating of plastic films is thus problematic, in particular, when the plastic film passes through the subsequent coating stations after a coating process, but there are no longer sufficient water molecules in the plastic film that can evaporate and establish thermal contact between the plastic film and the cooling device. The same problem exists for dry plastic films, such as those made from cyclo-olefin polymer (COP), even in a first coating process, as well as for band-shaped substrates made of metal or glass.

From the prior art, various approaches are known to solve this technical problem. For example, in U.S. Pat. No. 5,076,203 A, a gas is introduced directly at the point where the plastic film contacts the cooling cylinder.

A similar solution is described in DE 10 2013 212 395 A1. Here, water vapor is first sprayed onto the cooling cylinder, wherein the cooling cylinder is cooled until the water vapor transitions into the fixed state and thus an ice layer is formed between the cooling cylinder and a plastic film to be coated. During the coating process, this ice layer transitions into the liquid or gaseous state due to the heat input through the coating device and thus ensures a heat transfer between the cooling cylinder and the plastic film. The two solutions described above have the disadvantage that the gas and/or the water vapor introduced into the vacuum chamber can negatively influence the process atmosphere within the vacuum chamber.

In DE 10 2012 013 726 A1, it is suggested that a fluid for cooling a band-shaped substrate be introduced through the convex wall of a cooling device, between a band-shaped substrate and the cooling device. However, such a device is technically very complex.

Furthermore, methods are known in which a decisive increase in the contact pressure of a band-shaped substrate on a cooling cylinder is achieved by means of a Coulomb force through an electrostatic charging of the band-shaped substrate against the cooling cylinder.

For example, in EP 1 870 488 A1, it is suggested that the charge status of a film be measured and subsequently adjusted in a targeted manner. After the coating process, the film is decharged. A similar procedure is known from EP 2 073 249 A1. Here, a linear electron source is used in order to electrically charge a band-shaped substrate to be coated. In the process, the penetration depth of the electrons into the band-shaped substrate can be determined via the electron energy. The electrostatic charging of a band-shaped substrate can lead to a significant increase in the contact pressure on a cooling cylinder and thereby effectively improve coating processes in a vacuum. However, it is disadvantageous that a contact pressure increase after an electrostatic charging of band-shaped substrates cannot be used for metal films or bands or for plastic films which have an electrically conductive coating on the side facing the cooling cylinder (hereinafter referred to as the back side of a substrate). In these cases, the potential differences resulting from an electric charging between the band-shaped substrate and the cooling cylinder are short-circuited. Consequently, the charges wear off, whereby the basis for the formation of a Coulomb force is no longer given.

The invention is therefore based upon the technical problem of creating a device for coating a band-shaped substrate with which the disadvantages arising from the prior art can be overcome. In particular, with the device according to the invention, an improved cooling effect and a lower tendency toward wrinkle formation during coating will be achieved with metal, band-shaped substrates and also with plastic films having an electrically conductive coating on the back side.

A device for coating a band-shaped substrate within a vacuum chamber according to the invention comprises a coating device, which can be embodied as a magnetron sputter device or a vaporization device, for example; a cooling device with at least one convex surface area, which at least partially touches the band-shaped substrate at the time of the coating; and a coil system comprising at least a supply roller, a receiving roller, and multiple guide rollers. A device according to the invention is suitable, in particular, for coating band-shaped substrates which, at least on the side where the band-shaped substrate touches the cooling device, consist of an electrically conductive material. With such a device, both metal bands as well as plastic films which already have an electrically conductive coating on the back side can be coated.

A device according to the invention is also distinguished in that the cooling device, which can be configured, for example, as a convex forming shoulder or preferably as a cooling cylinder, has an electrically conductive base body and, at least in the convex surface area, an outer edge layer consisting of an electrically insulating material. It is also essential for a device according to the invention that at least the rollers and components of the coil system coming into contact with the back side of a band-shaped substrate to be coated do not have any electrically conductive connection to the electrical mass of the device and are thus configured to be potential-free with respect to the electrical mass of the device. In one embodiment, the entire coil system is therefore potential-free with respect to the electrical mass of the device. Furthermore, in a device according to the invention, an electrical voltage of at least 10 V is formed between the electrically conductive base body of the cooling device and the electrically conductive material of the substrate, wherein the electrically conductive base body of the cooling device can have, for example, the electrical mass potential of the device.

The electrical insulation between the base body of the cooling device and the band-shaped substrate in the form of the electrically insulating edge layer of the cooling device as well as the electrical voltage between the base body of the cooling device and the electrically conductive material of the band-shaped substrate allow the formation of electrostatic attraction forces between the band-shaped substrate and the cooling device, whereby a higher contact pressure of the substrate on the cooling device and consequently an improved cooling and reduced wrinkle formation are achieved.

In the process, the electrostatic attraction forces being formed become greater as the layer thickness of the electrically insulating edge layer of the cooling body becomes smaller and as the relative permittivity of the material of the electrically insulating edge layer of the cooling body is selected higher. However, neither parameter can be extended arbitrarily, because otherwise there will be electrical breaks through the electrically insulating edge layer of the cooling body. However, it is advantageous if a material having a relative permittivity greater than 2.5 is selected for the electrically insulating edge layer of the cooling body.

The electrically insulating outer edge layer of the cooling body can be formed, for example, by adhering a plastic film to the electrically conductive base body of the cooling device. The plastic film can consist, for example, of polyethylene terephthalate (PET), polypropylene (PP), polyimide (PI) or polyether ether ketone (PEEK), and can preferably have a thickness of 3 μm to 50 μm.

Alternatively, a layer consisting of an electrically insulating material can also be deposited on the electrically conductive base body of the cooling device. As the layer material for this purpose, a material can be used that has, for example, an oxide, nitride, or carbide, [and] at least one of the elements from the group of aluminum, silicon, tungsten, or titanium and which preferably is deposited on the electrically conductive base body of the cooling device with a layer thickness of 3 μm to 10 μm.

Various embodiments are also possible for the formation of an electrical voltage of at least 10 V between the electrically conductive base body of the cooling device and the electrically conductive material of the substrate. For example, a voltage of at least 10 V between the electrically conductive base body of the cooling device and a roller of the coil system can be generated by means of a power supply device, wherein a roller of the coil system coming into contact with the electrically conductive material of the substrate must be used. Here, it is irrelevant whether this roller is arranged before or after the coating device.

Alternatively, however, an electron source such as an electron beam generator can be used, from which accelerated electrons are emitted to the electrically conductive material of the substrate in order to generate an electrical charging of the electrically conductive material of the substrate, as a result of which an electrical voltage is formed between the electrically conductive base body of the cooling device and the electrically conductive material of the substrate.

In a preferred embodiment, the material to be deposited on the band-shaped substrate is vaporized by means of an electron beam generator. The primary electrons that are back-scattered by the vaporizing material, which also penetrate the band-shaped substrate to be coated, are sufficient to achieve an electrical charging of the electrically conductive material of the band-shaped substrate and thus cause the formation of an electrical voltage of at least 10 V between the electrically conductive base body of the cooling device and the electrically conductive material of the substrate.

The invention is described in greater detail below by means of exemplary embodiments.

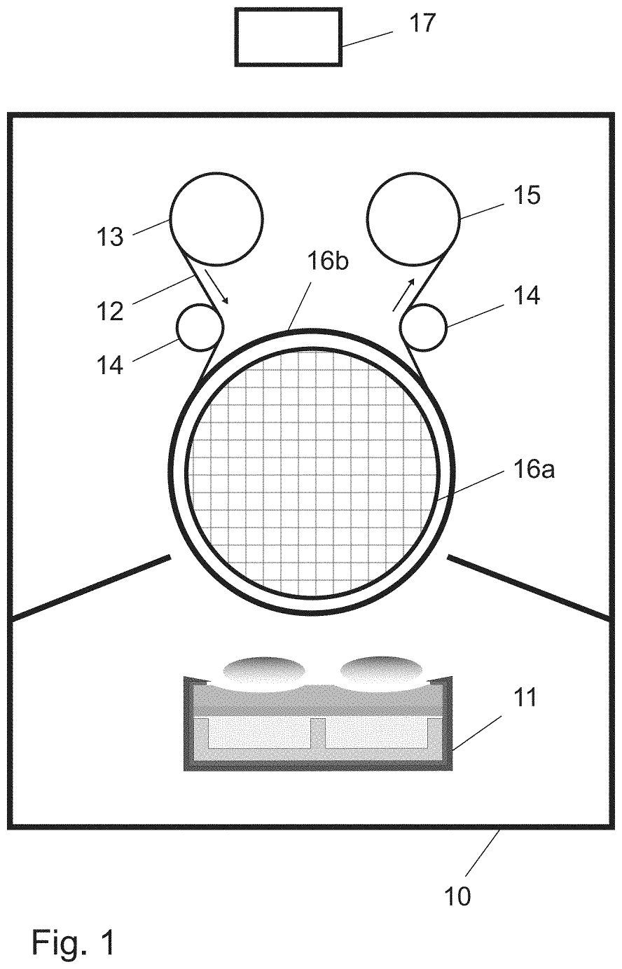

FIG. 1 is a schematic view of a device according to the invention, having a vacuum chamber 10. Within the vacuum chamber 10, there is a coating device 11 designed as a magnetron sputtering device, with which the band-shaped substrate 12 in the form of a metal film is to be coated. For this purpose, the band-shaped substrate 12 is first unwound from a supply roller 13 and then passed by a guide roller 14 consisting of an electrically conductive material. Then, it is partially entwined around a cooling device embodied as a cooling cylinder, which cools the band-shaped substrate 12 during the layer deposit by means of the coating device 11. After leaving the cooling device, the band-shaped substrate 12 is again passed by a guide roller 14 and subsequently wound on a receiving roller 15.

The cooling device embodied as a cooling cylinder has a cylinder-shaped base body 16a consisting of an electrically conductive material and an outer edge layer 16b consisting of an electrically insulating material on the convex lateral surface of the cylinder-shaped base body 16a. The outer edge layer 16b thus has the shape of a hollow cylinder and is designed with a relative permittivity greater than 2.5.

The supply roller 13, the receiving roller 15, and the guide rollers 14 form the coil system of the device according to the invention as seen in FIG. 1. While the base body 16a of the cooling device has the electrical mass potential of the device from FIG. 1, the entire coil system is designed to be potential-free and thus has no electrically conductive connection to the electrical mass potential of the device.

The device according to the invention as seen in FIG. 1 also includes a power supply device 17 arranged outside of the vacuum chamber 10, which generates an electrical voltage of about 1,000 V between the electrically conductive base body 16a of the cooling device and at least one of the guide rollers 14. Here, the contacting of the pivotably mounted guide rollers 14 with the pivotably mounted base body 16a of the cooling device can be realized, for example, by means of rubbing contacts. Because the band-shaped substrate 12, which is embodied as a metal film, touches the live guide roller 14, the electrical voltage provided by the power supply device 17 is also formed between the band-shaped substrate and the base body 16a of the cooling device. The electrically insulating edge layer 16b of the cooling device between the band-shaped substrate 12 and the electrically conductive base body 16a causes the formation of electrostatic forces which press the band-shaped substrate 12 to the cooling device. As a result, a better cooling effect is achieved, on the one hand, and the tendency of the band-shaped substrate to form wrinkles on the cooling device is reduced, on the other hand.

In order to prevent electrical overloads on the lateral edges of the cylindrical cooling device, it is advantageous for the longitudinal expansion of the edge layer 16b embodied as a hollow cylinder to be greater than the longitudinal expansion of the cylindrical base body 16a, so that the edge layer 16b protrudes over the cylindrical base body 16a on both sides of the cylindrical base body 16a. The size of such a lateral overhang of the edge layer 16b that is necessary in order to prevent lateral arcing events depends, among other things, upon the material used for the edge layer 16b, the edge layer thickness, and the level of the electrical voltage provided by the power supply 17. An exact value for a minimum required overhang can be determined using Paschen's Law. A lateral overhang of 1 cm each should be sufficient for most applications.

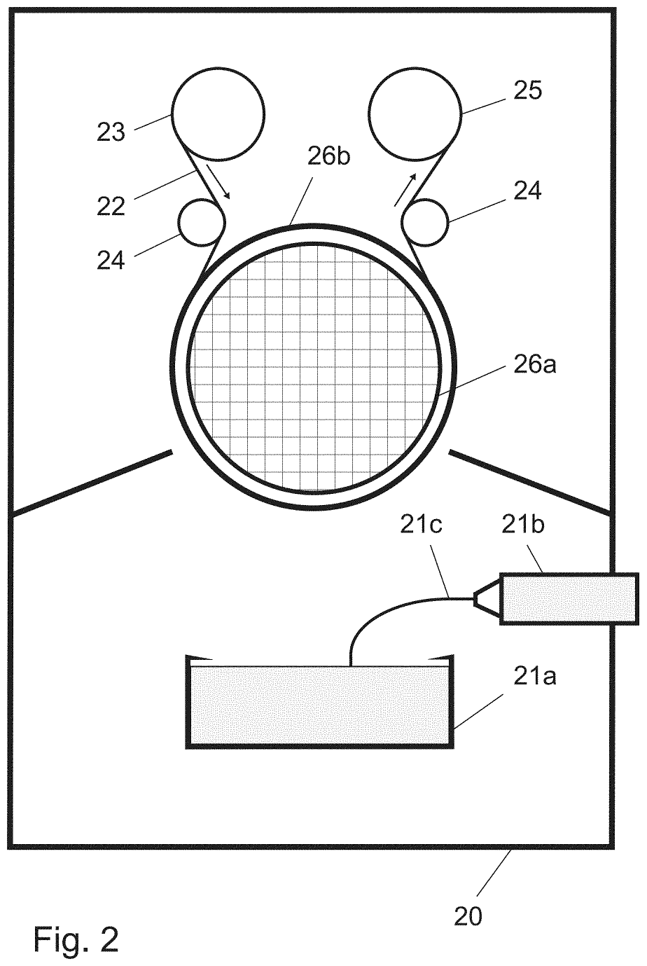

FIG. 2 shows a schematic view of an alternative device according to the invention, having a vacuum chamber 20. Within the vacuum chamber 20, there is a coating device, with which a band-shaped substrate 22 is to be coated. The coating device has a crucible 21a with vaporizing material, which is to be deposited on the band-shaped substrate, and an electron beam generator 21b for generating an electron beam 21c, with which the vaporizing material is vaporized.

The band-shaped substrate 22 is designed as a plastic film, which already has a layer consisting of an electrically conductive material on its back side. The band-shaped substrate 22 is first unwound from a supply roller 23 and then passed by a guide roller 24 consisting of an electrically conductive material. Then, it is partially entwined around a cooling device embodied as a cooling cylinder, which cools the band-shaped substrate 22 during the layer deposit. After leaving the cooling device, the band-shaped substrate 22 is again passed by a guide roller 24 and subsequently wound on a receiving roller 25.

The cooling device embodied as a cooling cylinder has a cylinder-shaped base body 26a consisting of an electrically conductive material and an outer edge layer 26b consisting of an electrically insulating material on the convex lateral surface of the cylinder-shaped base body 26a. The outer edge layer 26b thus has the shape of a hollow cylinder and is designed with a relative permittivity greater than 2.5.

The supply roller 23, the receiving roller 25, and the guide rollers 24 form the coil system of the device according to the invention as seen in FIG. 2. While the base body 26a of the cooling device has the electrical mass potential of the device from FIG. 2, the entire coil system is designed to be potential-free and thus has no electrically conductive connection to the electrical mass potential of the device.

Upon vaporization of the vaporizing material in the crucible 21a by means of the electron beam 21c, electrons from the vaporizing material are back-scattered, also penetrating the band-shaped substrate 22 to be coated and thereby charging the electrically conductive layer on the back side of the band-shaped substrate 22. Due to the electrically insulating edge layer 26b of the cooling device between the band-shaped substrate 22 and the electrically conductive base body 26a, an electrical voltage between several hundred to several thousand volts is generated between the band-shaped substrate 22 and the electrically conductive base body 26a, which causes the formation of electrostatic forces that press the band-shaped substrate 22 to the cooling device. As a result, a better cooling effect is achieved, on the one hand, and the tendency of the band-shaped substrate 22 to form wrinkles on the cooling device is reduced, on the other hand.

In order to prevent electrical overloads on the lateral edges of the cylindrical cooling device, it is also advantageous in this exemplary embodiment for the longitudinal expansion of the edge layer 26b embodied as a hollow cylinder to be greater than the longitudinal expansion of the cylindrical base body 26a, so that the edge layer 26b protrudes over the cylindrical base body 26a on both sides of the cylindrical base body 26a.

To clarify the use of and to hereby provide notice to the public, the phrases “at least one of <A>, <B>, . . . and <N>” or “at least one of <A>, <B>, <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. An apparatus for coating a band-shaped substrate within a vacuum chamber, the apparatus comprising:
a coating device;
a cooling device with at least one convex surface area which at least partially touches the band-shaped substrate at the time of the coating; and
a coil system comprising:
at least a supply roller,
a receiving roller, and
multiple guide rollers,
wherein the band-shaped substrate includes an electrically conductive material at least on the side where the band-shaped substrate touches the cooling device,
wherein the cooling device has an electrically conductive base body and, at least in the convex surface area, an outer edge layer consisting of an electrically insulating material,
wherein the coil system is designed to be potential-free with respect to the electrical mass of the device, and
wherein an electrical voltage of at least 10 V is formed between the electrically conductive base body of the cooling device and the electrically conductive material of the band-shaped substrate.

2. The apparatus of claim 1, wherein the outer edge layer of the cooling device has a relative permittivity greater than 2.5.

3. The apparatus of claim 1, wherein the outer edge layer of the cooling device is designed as a plastic film applied to the electrically conductive base body.

4. The apparatus of claim 3, wherein the plastic film consists of polyethylene terephthalate, polypropylene, polyimide, or polyether ether ketone.

5. The apparatus of claim 3, wherein the plastic film has a thickness of 3 μm to 50 μm.

6. The apparatus of claim 1, wherein the electrically conductive base body of the cooling device is coated with an electrically insulating material.

7. The apparatus of claim 6, wherein the electrically insulating material includes an oxide, a nitride or a carbide, and at least one of aluminum, silicon, tungsten, or titanium.

8. The apparatus of claim 6, wherein the electrically insulating material has a layer thickness of 3 μm to 10 μm.

9. The apparatus of claim 1, wherein the apparatus includes a power supply for generation of an electrical voltage of at least 10 V between the electrically conductive base body of the cooling device and at least one roller of the coil system.

10. The apparatus of claim 1, wherein the apparatus includes an electron beam generator configured to subject the electrically conductive material of the band-shaped substrate to accelerated electrons.

11. The apparatus of claim 1, wherein the apparatus includes an electron beam generator configured to generate an electron beam, for vaporization of a coating material, wherein electrons back-scattered by the coating material penetrate the band-shaped substrate.
